(19) United States
(12) Patent Application Publication
(10) Pub. No.: US 2025/0072229 A1
(43) Pub. Date: Feb. 27, 2025

(54) DISPLAY PANEL AND METHOD FOR MANUFACTURING THE SAME

(71) Applicant: HEFEI VISIONOX TECHNOLOGY CO., LTD., Hefei (CN)

(72) Inventors: Bo RAO, Hefei (CN); Xiaoxi SUN, Hefei (CN); Yuan YAO, Hefei (CN); Xuejing ZHU, Hefei (CN)

(73) Assignee: HEFEI VISIONOX TECHNOLOGY CO., LTD., Hefei (CN)

(21) Appl. No.: 18/944,425

(22) Filed: Nov. 12, 2024

(30) Foreign Application Priority Data
Jun. 28, 2024 (CN) 202410873016.7

(51) Int. Cl. H10K 59/122; H10K 59/12

(52) U.S. Cl. CPC H10K 59/122; H10K 59/1201

(57) ABSTRACT

A display panel includes: a substrate, a first partition structure and a plurality of light-emitting units. The first partition structure and the light-emitting units are disposed on a side of the substrate. The first partition structure encloses opening groups including at least one first opening and a second opening. The second opening is located between adjacent two of the opening groups, and each light-emitting unit is at least partially disposed in a corresponding first opening. A second partition structure is disposed in the second opening, and a gap is formed between the second partition structure and the first partition structure.

### CROSS-REFERENCE TO RELATED APPLICATIONS

This application claims priority benefit of Chinese patent application No. 2024108730167 filed on Jun. 28, 2024, entitled “DISPLAY PANEL AND METHOD FOR MANUFACTURING THE SAME”, the content of which is hereby incorporated by reference in its entirety.

### TECHNICAL FIELD

The present disclosure relates to the field of display technology, and in particular to a display panel and a method for manufacturing the same.

### BACKGROUND

Organic Light-emitting Diode (OLED) display technology is regarded as the most promising new flat panel display technology of the next generation. Compared with liquid crystal display technology, the OLED display technology has advantages of low energy consumption, low cost, self-luminescence, wide viewing angle, fast response speed and the like. However, the current OLED display panel has the problem of poor optical display effect.

### SUMMARY

Accordingly, it is necessary to provide a display panel and a manufacturing method for manufacturing the same that can improve the optical display effect.

In a first aspect, a display panel is provided, including: a substrate; a first partition structure disposed on a side of the substrate, the first partition structure enclosing a plurality of opening groups comprising at least one first opening, and a second opening located between adjacent two of the opening groups; a plurality of light-emitting units disposed on the side of the substrate, each light-emitting unit being at least partially disposed in a corresponding first opening; and a second partition structure disposed in the second opening, and a gap formed between the second partition structure and the first partition structure.

In a second aspect, a method for manufacturing a display panel is provided, including:
providing a substrate;
forming a first partition structure and a second partition structure that are spaced apart on a side of the substrate; the first partition structure enclosing a plurality of opening groups comprising a plurality of first openings, and a second opening, the second opening being located between adjacent two opening groups, and the second partition structure being located in the second opening; and
forming a plurality of light-emitting units on a side of the substrate facing the first partition structure, and each light-emitting unit being at least partially disposed in a corresponding first opening.

In a third aspect, a display panel is provided, including: a substrate; a first partition structure disposed on a side of the substrate, the first partition structure enclosing a plurality of first openings and a second opening located between adjacent two first openings; a plurality of light-emitting units disposed on the side of the substrate, each light-emitting unit being at least partially disposed in a corresponding first opening; and a second partition structure disposed in the second opening, and a gap being formed between the second partition structure and the first partition structure; wherein a first distance is defined between an orthographic projection of the first partition structure on the substrate and an orthographic projection of the second partition structure on the substrate, and the first distance is in a range of 6 μm to 6.5 μm.

In a fourth aspect, a display panel is provided, including: a substrate; a first partition structure disposed on a side of the substrate, the first partition structure enclosing a plurality of opening groups comprising at least one first opening, and a second opening located between adjacent two of the opening groups; a plurality of light-emitting units disposed on the side of the substrate, each light-emitting unit being at least partially disposed in a corresponding first opening; and a plurality of second partition structure disposed in the second opening at intervals, and a gap being formed between the second partition structure and the first partition structure.

The display panel according to the embodiment does not need to dispose the second opening between every adjacent two first openings, which is beneficial to reduce the size of the first partition structure between at least part of the adjacent two first openings and increase the aperture ratio of the display panel.

These and other objects, advantages, purposes and features will become apparent upon review of the following specification in conjunction with the drawings.

### BRIEF DESCRIPTION OF THE DRAWINGS

In order to more clearly illustrate the technical solutions in the embodiments or exemplary embodiments of the present disclosure, the drawings required in the description of the embodiments or exemplary embodiments will be briefly introduced below. Apparently, the drawings described below are only some embodiments of the present disclosure. For ordinary skills in the art, other drawings can be obtained based on these drawings without any creative effort.

FIG. 1 is a partial cross-sectional view of a display panel according to an embodiment.

FIG. 2 is a top view of a pixel definition layer according to an embodiment.

FIG. 3 is a top view of a pixel definition layer, a first partition structure, and a second partition structure according to an embodiment.

FIG. 4 is a cross-sectional view taken along a line H-H in FIG. 3.

FIG. 5 is a top view of FIG. 4.

FIG. 6 is another cross-sectional view taken along the line H-H in FIG. 3.

FIG. 7 is a top view of FIG. 6.

FIG. 8 is a flow chart of a method for manufacturing a display panel according to an embodiment.

FIG. 9 is a schematic view of a structure after a substrate is provided according to an embodiment.

FIG. 10 is a schematic view of a structure after a pixel definition material layer is formed according to an embodiment.

FIG. 11 is a schematic view of a structure after via holes and pixel openings are formed according to an embodiment.

FIG. 12 is a schematic view of a structure after a partition material layer is formed according to an embodiment.

FIG. 13 is a schematic view of a structure after a first opening is formed according to an embodiment.

FIG. 14 is a schematic view of a structure after a gap is formed according to an embodiment.

FIG. 15 is a schematic view of a structure after a light-emitting unit is formed according to an embodiment.

### ILLUSTRATION FOR REFERENCE SIGNS

100, display panel; 100a, display region; 100b, non-display region; 110, substrate; 120, first partition structure; 1201, first partition sub-structure; 1202, second partition sub-structure; 120a, partition material layer; 121, third partition portion; 121a, third partition material layer; 122, fourth partition portion; 122a, fourth partition material layer; 123a, opening group; 1231a, first opening group; 1232a, second opening group; 123, first opening; 124, second opening; 130, light-emitting device; 131, first electrode; 132, second electrode; 133, light-emitting unit; 140, second partition structure; 141, first partition portion; 142, second partition portion; 150, pixel definition layer; 150a, pixel definition material layer; 151a, pixel opening group; 1511a, first pixel opening group; 1512a, second pixel opening group; 151, pixel opening; 161, insulating layer; 162, conductive member; 163, via hole; 171, first encapsulation layer; 181, first edge; 182, second edge; 183, third edge; 184, fourth edge; 185, fifth edge; 186, sixth edge; 187, seventh edge; 188, eighth edge; 189, ninth edge; 1810, tenth edge; 1811, eleventh edge; 1812, twelfth edge; 1813, thirteenth edge; 1814, fourteenth edge.

### DETAILED DESCRIPTION

In order to order to facilitate the understanding of the present disclosure, the present disclosure will be described more fully below with reference to the relevant drawings. The preferred embodiments of the present disclosure are provided in the drawings. However, the present disclosure can be implemented in many different forms and is not limited to the embodiments described herein. On the contrary, the purpose of providing these embodiments is to make the understanding of the contents of the present disclosure more thorough and comprehensive.

It should be understood that although the terms “first”, “second”, etc. may be used herein to describe various elements, they do not indicate any order, quantity or importance, but are only used to distinguish different components. These terms are only used to distinguish one element from another element. For example, without departing from the scope of the present disclosure, the first element may be referred to as the second element, and similarly, the second element may be referred to as the first element. “Including” or “comprising” and similar words mean that the elements or objects described before the word covers the elements or objects listed after the word and their equivalents, without excluding other elements or objects.

Unless otherwise defined, all technical and scientific terms used herein have the same meaning as those commonly understood by those skilled in the art to which this disclosure belongs. The terms used herein in the specification of the present disclosure are only for the purpose of describing specific embodiments and are not intended to limit the present disclosure. The term “and/or” used herein includes any and all combinations of one or more of the associated listed items.

Organic Light-emitting Diode (OLED) display technology is regarded as the most promising new flat panel display technology of the next generation. Compared with liquid crystal display technology, the OLED display technology has advantages of low energy consumption, low cost, self-luminescence, wide viewing angle, fast response speed and the like.

In the related OLED display panel, the display panel may include a substrate, a partition structure and a light-emitting unit arranged on the substrate. The partition structure encloses a plurality of partition openings and a plurality of auxiliary openings. The auxiliary opening is arranged between each adjacent two partition openings. The light-emitting unit is at least partially arranged in the partition opening. A touch electrode may be arranged in the auxiliary opening.

However, in the above-mentioned display panel, since the touch electrode is arranged between adjacent two partition openings, and the distance between the touch electrode and the partition structure is large, the size of the auxiliary opening between the adjacent two partition openings is large, and the size of the partition structure between the adjacent two partition openings is large, which leads to a small aperture ratio of the display panel, and further leads to a poor optical display effect of the display panel.

In view of at least one of the above problems, embodiments of the present disclosure provide a display panel and a method for manufacturing the display panel, which can increase the aperture ratio of the display panel.

The display panel 100 according to the embodiments of the present disclosure will be described below with reference to FIGS. 1 to 15.

The display panel 100 according to the embodiments can be applied to a display device. The display device can be an electronic paper, a mobile phone, a tablet computer, a television, a display, a laptop computer, a digital photo frame, a smart bracelet, a smart watch, a super personal computer, a navigator, a wireless device, a personal digital assistant (PDA), a handheld or portable computer, a GPS receiver/navigator, a camera, an MP4 video player, a camcorder, a game console, a clock, a calculator, a television monitor, a computer monitor, a car display (for example, an odometer display, etc.), a cockpit controller and/or display, a display for a camera view (for example, a display for a rearview camera in a vehicle), an electronic billboard or sign, a projector, and other mobile or fixed terminals.

Exemplarily, the display panel 100 may be an organic light-emitting diode (OLED) display panel, a micro organic light-emitting diode (Micro OLED) display panel, a light-emitting diode (LED) display panel, a quantum dot light-emitting diode (QLED) display panel, a mini light-emitting diode (Mini LED) display panel, a micro light-emitting diode (Micro LED) display panel, or a liquid crystal display (LCD) panel. The embodiments of the present disclosure are described by taking an OLED display panel as an example.

The display panel 100 according to the embodiment of the present disclosure will be described below.

Referring to FIG. 1, the display panel 100 may include a substrate 110. The substrate 110 may provide support for other layers that are subsequently disposed thereon.

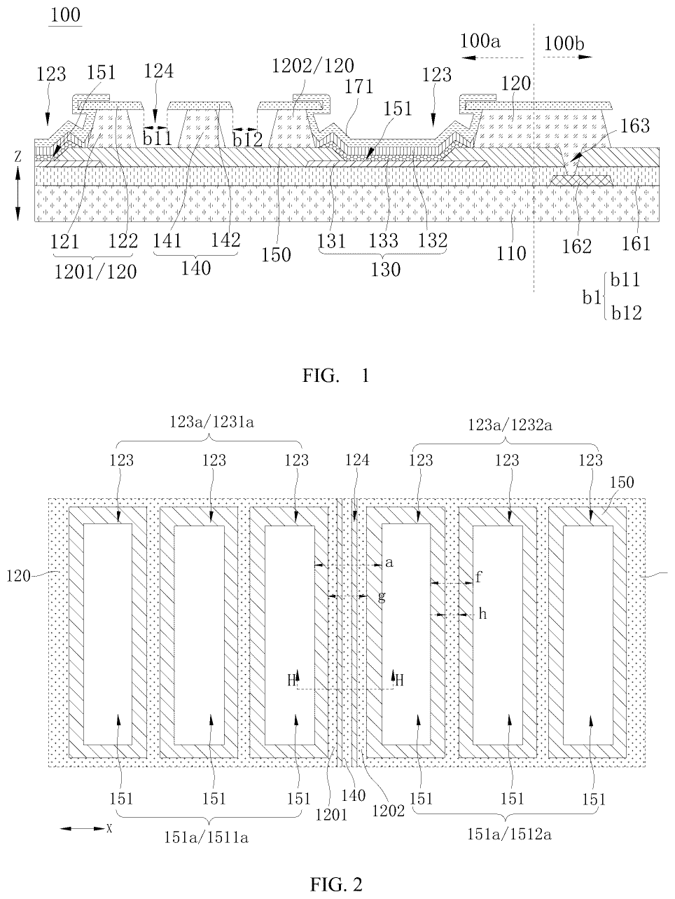

In some embodiments, referring to FIGS. 1 and 2, the display panel 100 may include a first partition structure 120 and a light-emitting unit 133 of a light-emitting device 130. For example, the light-emitting unit 133 may be made of a luminescent material. Both the first partition structure 120 and the light-emitting unit 133 may be disposed on a side of the substrate 110. The first partition structure 120 may enclose a first opening 123 and a second opening 124. The first opening 123 and the second opening 124 are spaced apart from each other. The light-emitting unit 133 and the first opening 123 may be disposed in correspondence. The light-emitting unit 133 is at least partially located in the corresponding first opening 123. A plurality of first openings 123 and a plurality of light-emitting units 133 are provided. The embodiment of the present disclosure is described by taking as an example that one light-emitting unit 133 may be partially disposed in one first opening 123.

Exemplarily, the first partition structure 120 may enclose a plurality of opening groups 123a. The opening groups 123a and the second opening 124 may be spaced apart. Each opening group 123a may include at least one first opening 123. When the same opening group 123a includes a plurality of first openings 123, the plurality of first openings 123 are spaced apart.

In some examples, the second opening 124 can be disposed between adjacent two opening groups 123a. In this way, it is not necessary to dispose the second opening 124 between every adjacent two first openings 123, which is beneficial to reduce the size of the first partition structure 120 between at least a part of adjacent two first openings 123, and is beneficial to increase the aperture ratio of the display panel 100.

In some other embodiments, the second opening 124 may be disposed between adjacent two first openings 123, thereby facilitating increasing flexibility in disposing the second opening 124.

The embodiments of the present disclosure are mainly described by taking the example that the second opening 124 is disposed between adjacent two opening groups 123a.

The display panel 100 may include a second partition structure 140, the first partition structure 120 and the second partition structure 140 according to the embodiments of the present disclosure are described below.

In some embodiments, referring to FIG. 1, the second partition structure 140 may be disposed in the second opening 124. The second partition structure 140 and the first partition structure 120 may be spaced apart from each other, that is, a gap may be formed between the second partition structure 140 and the first partition structure 120. The gap may be a part of the second opening 124 not covered by the second partition structure 140, that is, the gap may be a part of the second opening 124. By disposing the second partition structure 140 in the second opening 124 of the first partition structure 120, it is beneficial to reduce the total thickness of the first partition structure 120 and the second partition structure 140 in the display panel 100, thereby facilitating the thinning of the display panel 100.

Exemplarily, referring to FIG. 1, a distance between an orthographic projection of the first partition structure 120 on the substrate 110 and an orthographic projection of the second partition structure 140 on the substrate 110 may be defined as a first distance b1, and the first distance b1 may be in a range of 6 μm to 6.5 μm. The first distance b1 is less than or equal to 6.5 μm, as such, a distance between the second partition structure 140 and the first partition structure 120 is small, and a width of the first partition structure 120 between adjacent two opening groups 123a is small, which is beneficial to increase the aperture ratio of the display panel 100, and further improve the optical display effect of the display panel 100. In addition, the first distance b1 may be greater than or equal to 6 μm, so as to avoid the first distance b1 being too small, which can reduce the difficulty of spacing the second partition structure 140 from the first partition structure 120, and reduce the mutual interference between the second partition structure 140 and the first partition structure 120.

For example, the first distance b1 may be 6 μm, 6.1 μm, 6.2 μm, 6.3 μm, 6.4 μm, 6.5 μm, or any value between 6 μm and 6.5 μm.

Exemplarily, referring to FIG. 2, adjacent two opening groups 123a are defined as a first opening group 1231a and a second opening group 1232a that is adjacent to the first opening group 1231a. A distance g between adjacent two opening groups 123a is greater than a distance h between adjacent two first openings 123 in the same opening group 123a, thereby making the distance h between adjacent two first openings 123 in the same opening group 123a smaller, which is beneficial to improve the white light mixing effect of the multiple light-emitting devices 130 corresponding to the same opening group 123a. In addition, the distance g between adjacent two opening groups 123a is large, thereby reducing the difficulty of disposing the second opening 124 between the first opening group 1231a and the second opening group 1232a.

In some embodiments, the first partition structure 120 and/or the second partition structure 140 may be a structure formed by a single film layer, or a structure formed by stacking a plurality of film layers.

For example, referring to FIG. 1, the first partition structure 120 may include a third partition portion 121 and a fourth partition portion 122. The fourth partition portion 122 may be located on a side of the third partition portion 121 away from the substrate 110.

Exemplarily, referring to FIG. 1, the second partition structure 140 may include a first partition portion 141 and a second partition portion 142. The first partition portion 141 may be located on a side of the second partition portion 142 facing the substrate 110. For example, at least one of the first partition portion 141 and the second partition portion 142 may be configured as a touch electrode, thereby advantageously improving the touch performance of the display panel 100.

Exemplarily, the third partition portion 121 and the first partition portion 141 may be disposed in the same layer, thereby facilitating simplification of the manufacturing process of the third partition portion 121 and the first partition portion 141.

Exemplarily, the fourth partition portion 122 and the second partition portion 142 may be disposed in the same layer, thereby facilitating simplification of the manufacturing process of the fourth partition portion 122 and the second partition portion 142.

Exemplarily, referring to FIGS. 1 and 2, in the first partition structure 120 between adjacent two opening groups 123a, the first partition structure 120 may include a first partition sub-structure 1201 located in the first opening group 1231a and a second partition sub-structure 1202 located in the second opening group 1232a. The second partition structure 140 may be located between the first partition sub-structure 1201 and the second partition sub-structure 1202.

Exemplarily, a distance b11 between an orthographic projection of the first partition sub-structure 1201 on the substrate 110 and an orthographic projection of the second partition structure 140 on the substrate 110 can be equal to a distance b12 between an orthographic projection of the second partition sub-structure 1202 on the substrate 110 and an orthographic projection of the second partition structure 140 on the substrate 110, so that the distance b11 and the distance b12 can both reduced, which is beneficial to increase the aperture ratio of the display panel 100.

For example, the second partition structure 140 may have a first orthographic projection on the substrate 110, and the first partition structure 120 may have a second orthographic projection on the substrate 110.

Exemplarily, referring to FIGS. 2, 4 and 5, an orthographic projection of the first partition portion 141 on the substrate 110 may include a first edge 181 adjacent to the first opening group 1231a and a second edge 182 adjacent to the second opening group 1232a. An orthographic projection of the second partition portion 142 on the substrate 110 may include a third edge 183 adjacent to the first opening group 1231a and a fourth edge 184 adjacent to the second opening group 1232a.

Exemplarily, referring to FIGS. 2, 4 and 5, in the first partition sub-structure 1201, an orthographic projection of the third partition portion 121 on the substrate 110 may include a fifth edge 185 adjacent to the second partition structure 140 and a sixth edge 186 adjacent to the first opening group 1231a. An orthographic projection of the fourth partition portion 122 on the substrate 110 includes a seventh edge 187 adjacent to the second partition structure 140 and an eighth edge 188 adjacent to the first opening group 1231a. In the second partition sub-structure 1202, the orthographic projection of the third partition portion 121 on the substrate 110 may include a ninth edge 189 adjacent to the second partition structure 140 and a tenth edge 1810 adjacent to the second opening group 1232a. An orthographic projection of the fourth partition portion 122 on the substrate 110 includes an eleventh edge 1811 adjacent to the second partition structure 140 and a twelfth edge 1812 adjacent to the second opening group 1232a.

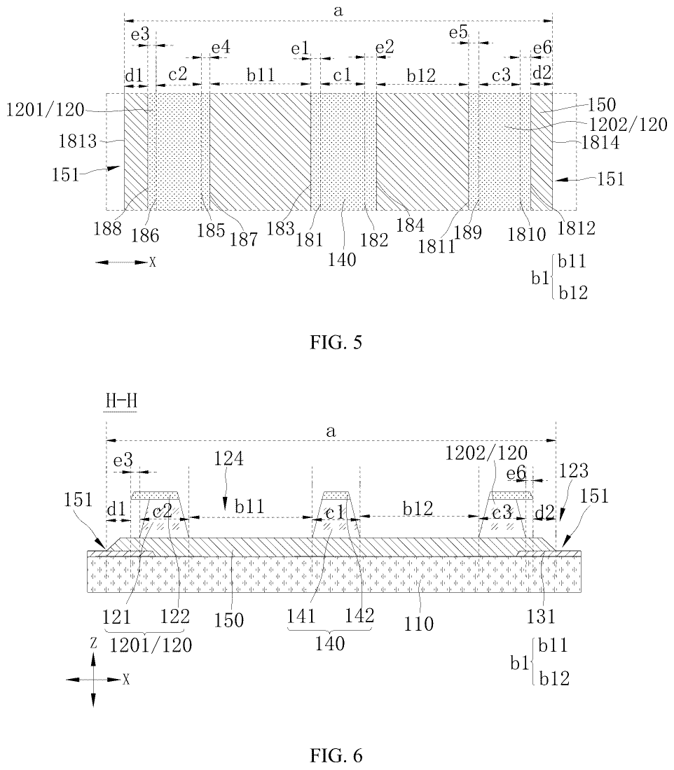

Exemplarily, referring to FIG. 5, a distance c1 between the first edge 181 and the second edge 182 is in a range of 4 μm to 4.5 μm, thereby preventing the distance c1 between the first edge 181 and the second edge 182 from being too small, so that the first partition portion 141 can provide better support for the second partition portion 142, thereby reducing the difficulty of disposing the second partition portion 142 on the first partition portion 141. In addition, the distance c1 between the first edge 181 and the second edge 182 can be prevented from being too large, thereby facilitating reducing the width of the first partition structure 120 between adjacent two opening groups 123a (i.e., the distance g between adjacent two opening groups 123a), thereby facilitating increasing the aperture ratio of the display panel 100.

Exemplarily, referring to FIG. 5, at least one of a distance c2 between the fifth edge 185 and the sixth edge 186 and a distance c3 between the ninth edge 189 and the tenth edge 1810 is in a range of 4 μm to 4.5 μm, thereby preventing such distance from being too small, so that the third partition portion 121 can provide better support for the fourth partition portion 122, thereby reducing the difficulty of disposing the fourth partition portion 122 on the third partition portion 121. In addition, such distance can be prevented from being too large, thereby facilitating reducing the width of the first partition structure 120 between adjacent two opening groups 123a, thereby facilitating increasing the aperture ratio of the display panel 100.

For example, referring to FIG. 5, at least one of the distance c1 between the first edge 181 and the second edge 182, the distance c2 between the fifth edge 185 and the sixth edge 186, and the distance c3 between the ninth edge 189 and the tenth edge 1810 can be 4 μm, 4.1 μm, 4.2 μm, 4.3 μm, 4.4 μm, 4.5 μm, and any value between 4 μm-4.5 μm.

Exemplarily, at least two of the distance c1 between the first edge 181 and the second edge 182, the distance c2 between the fifth edge 185 and the sixth edge 186, and the distance c3 between the ninth edge 189 and the tenth edge 1810 may be the same, so that at least two of the third partition portion 121 of the first partition sub-structure 1201, the third partition portion 121 of the second partition sub-structure 1202, and the first partition portion 141 may be set to be narrower, which is beneficial to increase the aperture ratio of the display panel 100.

Exemplarily, referring to FIGS. 4 and 5, the sixth edge 186 and the tenth edge 1810 can be located between the eighth edge 188 and the twelfth edge 1812, so that the fourth partition portion 122 can protrude from a sidewall of the third partition portion 121 away from the second partition structure 140. A recessed undercut structure is formed between the sidewall of the third partition portion 121 away from the second partition structure 140 and the fourth partition portion 122, so that the first partition structure 120 can partition the light-emitting units 133 in adjacent two first openings 123 during the process of forming the light-emitting units 133, thereby eliminating the use of the fine metal mask plate to save the manufacturing cost of the display panel 100.

For example, an etching rate of the third partition portion 121 can be greater than an etching rate of the fourth partition portion 122. During the etching process of the first partition structure 120, it is beneficial to form a concave undercut structure between the sidewall of the third partition portion 121 away from the second partition structure 140 and the fourth partition portion 122.

Exemplarily, referring to FIG. 5, at least one of a distance e3 between the sixth edge 186 and the eighth edge 188 and a distance e6 between the tenth edge 1810 and the twelfth edge 1812 may be in a range of 1 μm to 5 μm, thereby preventing such distance from being too small. In the process of forming the light-emitting unit 133, the first partition structure 120 can better partition the light-emitting units 133 in adjacent two first openings 123. In addition, such distance can be prevented from being too large, thereby facilitating reduction of the width of the first partition structure 120 between adjacent two opening groups 123a, and facilitating increasing the aperture ratio of the display panel 100.

For example, at least one of the distance e3 between the sixth edge 186 and the eighth edge 188 and the distance e6 between the tenth edge 1810 and the twelfth edge 1812 may be 1 μm, 1.1 μm, 1.2 μm, 1.3 μm, 1.4 μm, 1.5 μm or any value between 1 μm and 1.5 μm.

Referring to FIGS. 4 and 5, it will be described that the first edge 181 and the second edge 182 are located between the third edge 183 and the fourth edge 184, and the seventh edge 187 and the eleventh edge 1811 are located between the fifth edge 185 and the ninth edge 189.

In some embodiments, the first opening 123 and the gap between the first partition structure 120 and the second partition structure 140 can be formed in the same patterning process, thereby simplifying the manufacturing process of the first partition structure 120 and the second partition structure 140. Referring to FIGS. 4 and 5, the orthographic projection of the third partition portion 121 on the substrate 110 can be located within the orthographic projection of the fourth partition portion 122 on the substrate 110. The seventh edge 187 and the eleventh edge 1811 are located between the fifth edge 185 and the ninth edge 189. The orthographic projection of the first partition portion 141 on the substrate 110 can be located within the orthographic projection of the second partition portion 142 on the substrate 110. The first edge 181 and the second edge 182 are located between the third edge 183 and the fourth edge 184. In this case, the distance b11 between the first partition sub-structure 1201 and the second partition structure 140 can be equal to the distance between the third edge 183 and the seventh edge 187. The distance b12 between the second partition sub-structure 1202 and the second partition structure 140 may be equal to the distance between the fourth edge 184 and the eleventh edge 1811.

Exemplarily, at least one of a distance e1 between the first edge 181 and the third edge 183, a distance e2 between the second edge 182 and the fourth edge 184, a distance e4 between the fifth edge 185 and the seventh edge 187, and a distance e5 between the ninth edge 189 and the eleventh edge 1811 can be in a range of lum to 1.5 μm, thereby preventing such distance from being too small, so that the fourth partition portion 122 can better shield the third partition portion 121, thereby reducing the reflection of ambient light by the third partition portion 121. In addition, the second partition portion 142 can better shield the first partition portion 141, thereby reducing the reflection of ambient light by the first partition portion 141. In addition, the distances can be prevented from being too large, which is beneficial to reduce the width of the first partition structure 120 between adjacent two opening groups 123a, and is beneficial to increase the aperture ratio of the display panel 100.

Exemplarily, at least one of the distance e1 between the first edge 181 and the third edge 183, the distance e2 between the second edge 182 and the fourth edge 184, the distance e4 between the fifth edge 185 and the seventh edge 187, and the distance e5 between the ninth edge 189 and the eleventh edge 1811 can be 1 μm, 1.1 μm, 1.2 μm, 1.3 μm, 1.4 μm, 1.5 μm or any value between 1 μm and 1.5 μm.

Exemplarily, at least two of the distance e1 between the first edge 181 and the third edge 183, the distance e2 between the second edge 182 and the fourth edge 184, the distance e4 between the fifth edge 185 and the seventh edge 187, and the distance e5 between the ninth edge 189 and the eleventh edge 1811 may be the same, so that at least two of the distance e1 between the first edge 181 and the third edge 183, the distance e2 between the second edge 182 and the fourth edge 184, the distance e4 between the fifth edge 185 and the seventh edge 187, and the distance e5 between the ninth edge 189 and the eleventh edge 1811 may be reduced, which is beneficial to increase the aperture ratio of the display panel 100.

Exemplarily, referring to FIGS. 4 and 5, a distance a between adjacent two pixel opening groups 151a is b11+b12+c1+c2+c3+d1+d2+e1+e2+e3+e4+e5+e6.

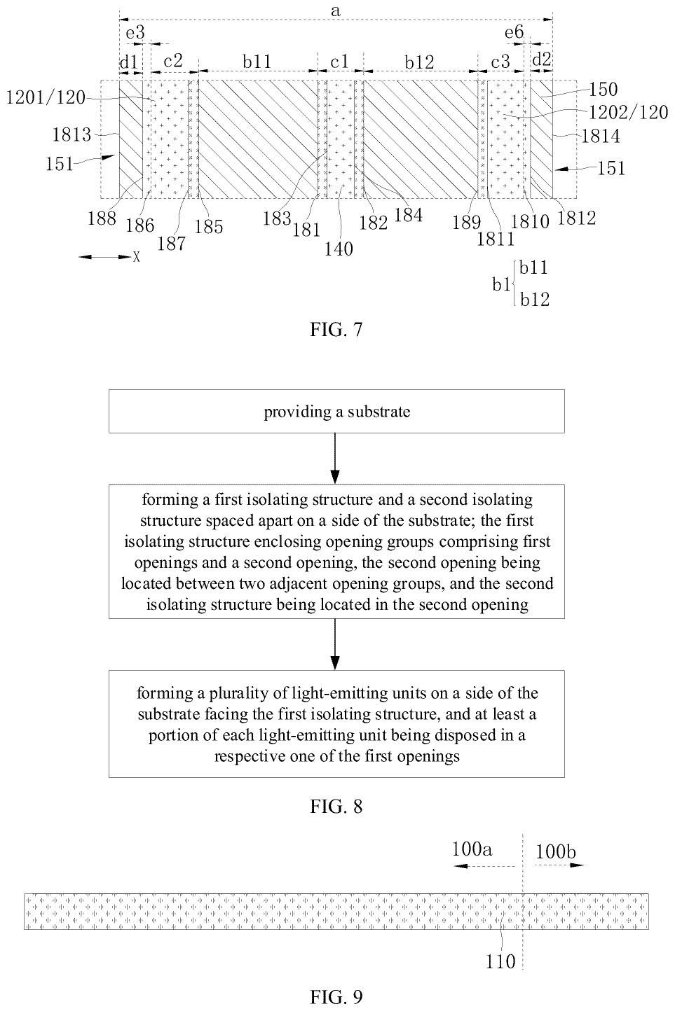

Referring to FIGS. 6 and 7, it will be described that the third edge 183 and the fourth edge 184 are located between the first edge 181 and the second edge 182, and the fifth edge 185 and the ninth edge 189 are located between the seventh edge 187 and the eleventh edge 1811.

In some embodiments, the first opening 123 and the gap between the first partition structure 120 and the second partition structure 140 can be formed by two patterning processes. The first opening 123 can be formed by a first patterning process, and the gap between the first partition structure 120 and the second partition structure 140 can be formed by a second patterning process. In this way, since the undercut structure between the sidewall of the third partition part 121 away from the second partition structure 140 and the fourth partition part 122 has been formed in the first patterning process, there is no need to form an undercut structure between the sidewall of the third partition part 121 adjacent to the second partition structure 140 and the fourth partition part 122, and between the first partition part 141 and the second partition part 142, so that there is no need to over-etch a partition material layer 120a in the second patterning process (this principle will be specifically described in the following embodiment). As such, the distance between the first partition structure 120 and the second partition structure 140 can be greatly reduced, and the aperture ratio of the display panel 100 can be greatly increased. In this case, the third edge 183 and the fourth edge 184 may be located between the first edge 181 and the second edge 182, and the fifth edge 185 and the ninth edge 189 may be located between the seventh edge 187 and the eleventh edge 1811. The distance b11 between the first partition sub-structure 1201 and the second partition structure 140 may be equal to the distance between the first edge 181 and the fifth edge 185. The distance b12 between the second partition sub-structure 1202 and the second partition structure 140 may be equal to the distance between the second edge 182 and the ninth edge 189.

For example, by forming the first opening 123 and the gap between the first partition structure 120 and the second partition structure 140 by two patterning processes, the first distance b1 can be reduced to a range of 3 μm to 3.5 μm, thereby better improving the aperture ratio of the display panel 100. For example, the first distance b1 can be 3 μm, 3.1 μm, 3.2 μm, 3.3 μm, 3.4 μm, 3.5 μm, or any value between 3 μm and 3.5 μm.

Exemplarily, referring to FIGS. 6 and 7, the distance a between adjacent two pixel opening groups 151a is b11+b12+c1+c2+c3+d1+d2+e3+e6. The first opening 123 and the gap between the first partition structure 120 and the second partition structure 140 is formed by two patterning processes. Compared with a (=b11+b12+c1+c2+c3+d1+d2+e1+e2+e3+e4+e5+e6) in FIGS. 4 and 5, distances e1, e2, e4, and e5 are reduced, which can better increase the aperture ratio of the display panel 100.

Exemplarily, referring to FIGS. 6 and 7, in the first partition sub-structure 1201, the seventh edge 187 is located within the orthographic projection of the surface of the third partition portion 121 away from the substrate 110 on the substrate 110, thereby helping to reduce the difficulty of manufacturing the sidewall of the first partition sub-structure 1201 facing the second partition structure 140.

Exemplarily, referring to FIGS. 6 and 7, in the second partition sub-structure 1202, the eleventh edge 1811 is located within the orthographic projection of the surface of the third partition portion 121 away from the substrate 110 on the substrate 110, thereby helping to reduce the difficulty of manufacturing the sidewall of the second partition sub-structure 1202 facing the second partition structure 140.

Exemplarily, at least one of the third edge 183 and the fourth edge 184 is located within the orthographic projection of the surface of the first partition portion 141 away from the substrate 110 on the substrate 110, thereby facilitating reducing the difficulty of manufacturing the second partition structure 140.

For example, referring to FIG. 6, the distance between the first partition structure 120 and the second partition structure 140 can be gradually increased in a direction from the substrate 110 to the first partition structure 120, which is beneficial to reduce the difficulty of forming the gap between the first partition structure 120 and the second partition structure 140, and is also beneficial for the film layer formed in the gap to climb onto the first partition structure 120 and the second partition structure 140.

In some embodiments, referring to FIGS. 2 and 4, a width of the third partition portion 121 in the direction from the first opening group 1231a to the second opening group 1232a may be defined as a first width. The first width gradually decreases from in the direction from the substrate 110 to the first partition structure 120, so that the shape of the third partition portion 121 is relatively simple, and the manufacturing process of the third partition portion 121 may be simplified. For example, in the cross section in the direction perpendicular to the substrate 110, the cross-sectional shape of the third partition portion 121 may be a trapezoid.

In some other embodiments, the third partition portion 121 may include a first partition sub-portion and a second partition sub-portion. The second partition sub-portion is located on a side of the first partition sub-portion away from the fourth partition portion 122. The orthographic projection of the first partition sub-portion on the substrate 110 may be located within the orthographic projection of the second partition sub-portion on the substrate 110. Thus, when the first partition structure 120 is made of a conductive material, the first partition structure 120 includes the first partition sub-portion, the second partition sub-portion, and the fourth partition portion 122 that are stacked, which can reduce the resistance of the first partition structure 120, thereby reducing the power consumption of the display panel 100.

In some embodiments, referring to FIGS. 2 and 4, a width of the first partition portion 141 in the direction from the first opening group 1231a to the second opening group 1232a is defined as a second width. The second width gradually decreases in the direction from the substrate 110 to the first partition structure 120, so that the shape of the first partition portion 141 is relatively simple, and the manufacturing process of the first partition portion 141 can be simplified. For example, in the cross section in the direction perpendicular to the substrate 110, the cross-sectional shape of the first partition portion 141 can be a trapezoid.

In some other embodiments, the first partition portion 141 includes a third partition sub-portion and a fourth partition sub-portion. The fourth partition sub-portion is located on the side of the third partition sub-portion away from the second partition portion 142. The orthographic projection of the third partition sub-portion on the substrate 110 is located within the orthographic projection of the fourth partition sub-portion on the substrate 110. In this way, the second partition structure 140 includes the third partition sub-portion, the fourth partition sub-portion, and the second partition portion 142 that are stacked, which is beneficial to reduce the resistance of the second partition structure 140.

Exemplarily, at least one of the first partition sub-portion, the second partition sub-portion, the fourth partition portion 122, the third partition sub-portion, the fourth partition sub-portion, and the second partition portion 142 may includes a conductive material (for example, metal). At least one of the first partition sub-portion, the second partition sub-portion, the fourth partition portion 122, the third partition sub-portion, the fourth partition sub-portion, and the second partition portion 142 may be made of one or more materials selected from the group consisting of a metal such as titanium, silver, copper, aluminum or molybdenum, or an alloy, or a conductive oxide (such as indium tin oxide (ITO), indium zinc oxide (IZO), zinc oxide (ZnO), aluminum zinc oxide (AZO)), zinc gallium oxide, titanium tantalum oxide, tin oxide, cadmium oxide, indium oxide.

In some other examples, at least one of the first partition sub-portion, the second partition sub-portion, and the fourth partition portion 122 may be made of an insulating material, which is not limited herein.

For example, the first partition sub-portion and the third partition sub-portion may be disposed in the same layer, thereby facilitating simplification of the manufacturing process of the first partition sub-portion and the third partition sub-portion.

For example, the second partition sub-portion and the fourth partition sub-portion may be disposed in the same layer, thereby facilitating simplification of the manufacturing process of the second partition sub-portion and the fourth partition sub-portion.

For example, the fourth partition portion 122 and/or the second partition portion 142 may be made of a material including at least one of titanium and molybdenum.

For example, the first partition sub-portion and/or the third partition sub-portion may be made of a material including at least one of aluminum, copper, and silver.

For example, the second partition sub-portion and/or the fourth partition sub-portion may be made of a material including at least one of titanium and molybdenum.

Referring to FIG. 1, when the first partition structure 120 includes a conductive material, a second electrode 132 of the light-emitting device 130 may be electrically connected to the first partition structure 120. In this way, it is convenient to electrically connect the second electrode 132 to a second power line through the first partition structure 120, thereby optimizing the wiring arrangement of the display panel 100.

When the first partition sub-portion is made of a conductive material, the second electrode 132 may be electrically connected to the first partition sub-portion. In this way, the second electrodes 132 located in the first openings 123 may be connected as a whole through the first partition sub-portions and connected to the second power line to apply a power supply voltage to the second electrode 132, thereby optimizing the wiring arrangement of the display panel 100.

When the second partition sub-portion is made of a conductive material, the second electrode 132 may be electrically connected to the second partition sub-portion. The principle thereof has been set forth above, and will not be repeatedly described herein.

When the first partition sub-portion and the second partition sub-portion are both made of conductive materials, the second electrode 132 can be electrically connected to at least one of the first partition sub-portion and the second partition sub-portion. For example, the second electrode 132 is connected to both the first partition sub-portion and the second partition sub-portion, thereby improving the connection stability between the second electrode 132 and the first partition structure 120.

In some embodiments, a plurality of second partition structures 140 are spaced apart in the second opening 124. A gap is formed between each of the second partition structures 140 and the first partition structure 120, so that the number of second partition structures 140 can be increased, which can increase the diversity of the patterns of the second partition structures 140.

For the configuration of the first partition structure 120, reference may be made to patents PCT/CN2023/134518, 202310759370.2, 202310740412.8, 202310707209.0, 202311346196.5, and 202310909421.5.

In some embodiments, referring to FIGS. 1 to 3, the display panel 100 may include a pixel definition layer 150. The pixel definition layer 150 may be disposed on a side of the first partition structure 120 adjacent to the substrate 110. The pixel definition layer 150 encloses a plurality of pixel opening groups 151a. Each pixel opening group 151a may include a plurality of pixel openings 151. The pixel opening group 151a is disposed corresponding to the opening group 123a. The first opening 123 is in communication with the corresponding pixel opening 151. An orthographic projection of the pixel opening 151 on the substrate 110 is located within the orthographic projection of the first opening 123 on the substrate 110. The light-emitting unit 133 of the light-emitting device 130 may be at least partially located in the pixel opening 151. In this way, by disposing the pixel definition layer 150, it is convenient to dispose the light-emitting device 130 on the substrate 110.

In some embodiments, the pixel definition layer 150 may be omitted, which can help to simplify the structure of the display panel 100, reduce the manufacturing cost of the display panel 100, and make the display panel 100 thinner and lighter. The embodiments of the present disclosure are described below by taking the display panel 100 provided with the pixel definition layer 150 as an example.

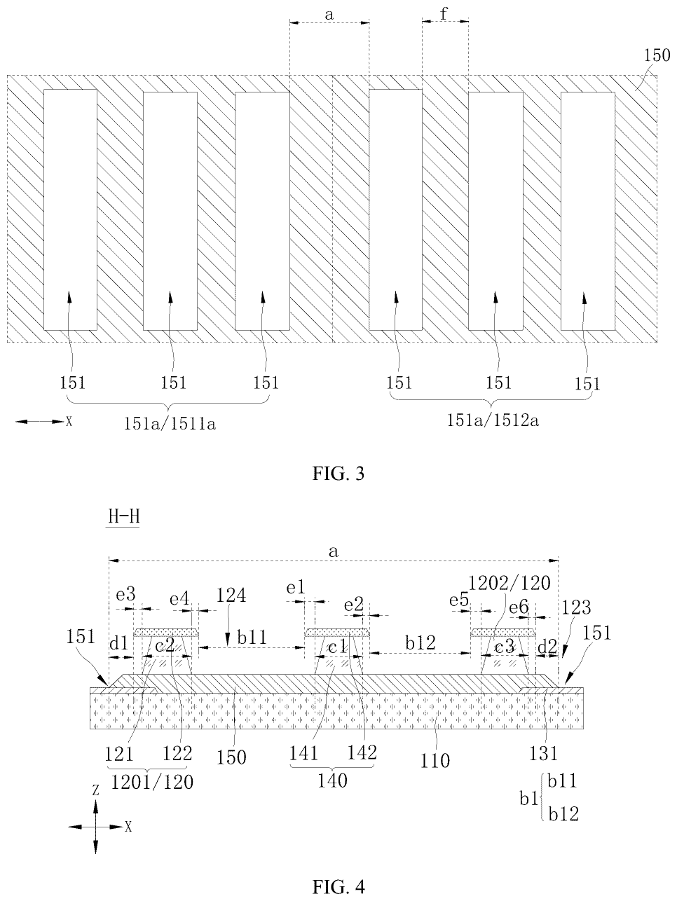

For example, referring to FIG. 3, the distance a between adjacent two pixel opening groups 151a may be in a range of 34 μm to 42.5 μm, so that this distance may be prevented from being too small, which is beneficial to reduce the difficulty of disposing the first partition structure 120 and the second partition structure 140. In addition, such distance may be prevented from being too large, which is beneficial e to increase the aperture ratio of the display panel 100. For example, the distance may be 34 μm, 36 μm, 38 μm, 40 μm, 42.5 μm, or any value between 34 μm and 42.5 μm.

Exemplarily, in an embodiment where the first opening 123, the gap between the first partition structure 120 and the second partition structure 140 are formed by two patterning processes, the first distance b1 can be greatly reduced, so that the distance a between adjacent two pixel opening groups 151a can be reduced to 24 μm to 30.5 μm, thereby better improving the aperture ratio of the display panel 100. For example, the distance can be 24 μm, 26 μm, 28 μm, 30.5 μm, or any value between 24 μm and 30.5 μm.

For example, referring to FIG. 3, in the same pixel opening group 151a, a distance f between adjacent two pixel openings 151 may be in a range of 12 μm to 14 μm, so that this distance may be prevented from being too small, so as to alleviate the color mixing of the light-emitting units 133 in the adjacent two pixel openings 151 and improve the color deviation. In addition, such distance may be prevented from being too large, which can increase the aperture ratio of the display panel 100. For example, the distance may be 12 μm, 12.5 μm, 13 μm, 14 μm, or any value between 12 μm and 14 μm.

Exemplarily, referring to FIG. 2, adjacent two pixel opening groups 151a are defined as a first pixel opening group 1511a and a second pixel opening group 1512a, respectively. The first pixel opening group 1511a and the first opening group 1231a are disposed in correspondence. The second pixel opening group 1512a and the second opening group 1232a are disposed in correspondence. An orthographic projection of a portion of the pixel definition layer 150 located between the adjacent two pixel opening groups 151a on the substrate 110 includes a thirteenth edge 1813 (FIG. 5) adjacent to the first pixel opening group 1511a and the fourteenth edge 1814 (FIG. 5) adjacent to the second pixel opening group 1512a. The eighth edge 188 and the twelfth edge 1812 are located between the thirteenth edge 1813 and the fourteenth edge 1814.

Exemplarily, referring to FIG. 3, the distance a between adjacent two pixel opening groups 151a is greater than the distance f between adjacent two pixel openings 151 in the same pixel opening group 151a, thereby avoiding the distance f between adjacent two pixel openings 151 in the same pixel opening group 151a being too large, which is beneficial to improve the white light mixing effect of the multiple light-emitting devices 130 corresponding to the same pixel opening group 151a. In addition, the distance a between adjacent two pixel opening groups 151a is large, thereby reducing the difficulty of disposing the second opening 124 between the first pixel opening group 1511a and the second pixel opening group 1512a.

For example, referring to FIGS. 4 and 5, at least one of a distance d1 between the eighth edge 188 and the thirteenth edge 1813 and a distance d2 between the twelfth edge 1812 and the fourteenth edge 1814 may be in a range of 2 μm to 3.5 μm, thereby preventing such distance from being too small, which is beneficial to prevent the first partition structure 120 from entering the pixel opening 151 and contacting a first electrode 131. In addition, the distance may be prevented from being too large, which is beneficial to increase the aperture ratio of the display panel 100. For example, the distance may be 2 μm, 2.5 μm, 3 μm, 3.5 μm, or any value between 2 μm and 3.5 μm.

Exemplarily, the distance d1 between the eighth edge 188 and the thirteenth edge 1813 can be equal to the distance d2 between the twelfth edge 1812 and the fourteenth edge 1814, so that the distance d1 between the eighth edge 188 and the thirteenth edge 1813 and the distance d2 between the twelfth edge 1812 and the fourteenth edge 1814 can be small, which is beneficial to increase the aperture ratio of the display panel 100.

Exemplarily, referring to FIG. 1, the display panel 100 may include a display region 100a and a non-display region 100b, and the pixel opening 151 is located in the display region 100a.

Exemplarily, referring to FIG. 1, in the non-display region 100b, the pixel definition layer 150 encloses a via hole 163. For example, a conductive member 162 may be electrically connected to the first partition structure 120 that is formed subsequently through the via hole 163.

The light-emitting device 130 according to the embodiments of the present disclosure is described below.

In some embodiments, referring to FIG. 1, the light-emitting device 130 may include a first electrode 131, a light-emitting unit 133, and a second electrode 132 that are sequentially stacked in a direction away from the substrate 110. The first electrode 131 may be located on a side of the light-emitting unit 133 facing the substrate 110. For example, the first electrode 131 may be located on a side of the pixel definition layer 150 facing the substrate 110, and the pixel opening 151 exposes at least a portion of the first electrode 131. At least a portion of the light-emitting unit 133 and at least a portion of the second electrode 132 may be located within the pixel opening 151 and the first opening 123. For example, a plurality of light-emitting devices 130 may be provided. The plurality of light-emitting devices 130 may be arranged in an array. Correspondingly, a plurality of light-emitting units 133 and a plurality of first electrodes 131 may be provided.

For example, one of the first electrode 131 and the second electrode 132 may be an anode, and the other of the first electrode 131 and the second electrode 132 may be a cathode. The embodiments of the present disclosure are described below by taking the first electrode 131 as an anode and the second electrode 132 as a cathode as an example.

Exemplarily, the first electrode 131 may be electrically connected to a pixel driving circuit. The pixel driving circuit may be electrically connected to a first power line. The second electrode 132 may be electrically connected to a second power line. One of the first power line and the second power line is configured to transmit a high voltage, and the other of the first power line and the second power line is configured to transmit a low voltage. For example, the first power line is configured to transmit a high voltage, and the second power line is configured to transmit a low voltage.

Exemplarily, the light-emitting device 130 may further include one or more of a hole injection layer (HIL), a hole transport layer (HTL), an electron injection layer (EIL), an electron transport layer (ETL), a hole fourth partition portion 122 (hole block layer, HBL) and an electron fourth partition portion 122 (electron block layer, EBL).

Exemplarily, the plurality of light-emitting devices 130 may include a first light-emitting device, a second light-emitting device, and a third light-emitting device that have different light-emitting colors. The plurality of light-emitting devices 130 include, but are not limited to, a red light-emitting device, a green light-emitting device, and a blue light-emitting device. In some other examples, the plurality of light-emitting devices 130 may further include a white light-emitting device. For example, the light-emitting unit 133 of the red light-emitting device is formed of a red light-emitting material, the light-emitting unit 133 of the green light-emitting device is formed of a green light-emitting material, and the light-emitting unit 133 of the blue light-emitting device is formed of a blue light-emitting material.

An encapsulation layer according to the embodiments of the present disclosure is described below.

In some embodiments, the display panel includes the encapsulation layer. The encapsulation layer is located on a side of the light-emitting device 130 and a side of the first partition structure 120 away from the substrate 110. At least one encapsulation layer may be provided. When a plurality of encapsulation layers are provided, the plurality of encapsulation layers are arranged in sequence in a thickness direction of the substrate 110 (i.e., a direction Z shown in FIG. 1).

In some embodiments, referring to FIG. 1, the encapsulation layer may include a first encapsulation layer 171. The first encapsulation layer 171 may be located on a side of the light-emitting device 130 away from the substrate 110. The first encapsulation layer 171 includes a plurality of encapsulation portions. The plurality of encapsulation portions are disposed in correspondence on the side of the light-emitting device 130 away from the substrate 110. The encapsulation portions may extend from a side surface of the first partition structure 120 to a side of the first partition structure 120 away from the substrate 110, so that the encapsulation portions have a better protection effect on the light-emitting device 130.

In some embodiments, the encapsulation layer may further include a second encapsulation layer and a third encapsulation layer. The second encapsulation layer is located between the first encapsulation layer 171 and the third encapsulation layer.

In some embodiments, the second encapsulation layer may be made of an organic material, which is helpful to relieve the stress of the film layer. For example, the second encapsulation layer may be manufactured by coating or other methods.

In some embodiments, at least one of the first encapsulation layer 171 and the third encapsulation layer may be made of an inorganic material. The encapsulation layer made of an inorganic material has a better barrier effect on moisture and oxygen, thereby achieving a better encapsulation effect. For example, a deposition process such as atomic layer deposition (ALD), physical vapor deposition (PVD), or chemical vapor deposition (CVD) may be adopted.

In some embodiments, referring to FIG. 1, the display panel 100 may include the display region 100a and the non-display region 100b. The display region 100a may be used to display a picture. The non-display region 100b may be disposed adjacent to the display region 100a. The non-display region 100b may be located on at least one of the sides of the display region 100a. For example, the non-display region 100b may be disposed around the display region 100a, and the non-display region 100b may form a “black border” surrounding the display region 100a.

A method for manufacturing the display panel 100 according to an embodiment of the present disclosure are described below.

The method for manufacturing the display panel 100 according to the embodiments of the present disclosure can be used to manufacture the display panel 100 of the above embodiments. Referring to FIG. 8, the method for manufacturing the display panel 100 may include the following steps of S100 to S300.

At S100, a substrate is provided.

First, referring to FIG. 9, the substrate 110 is provided. The substrate 110 can provide support for film layers that are subsequently disposed.

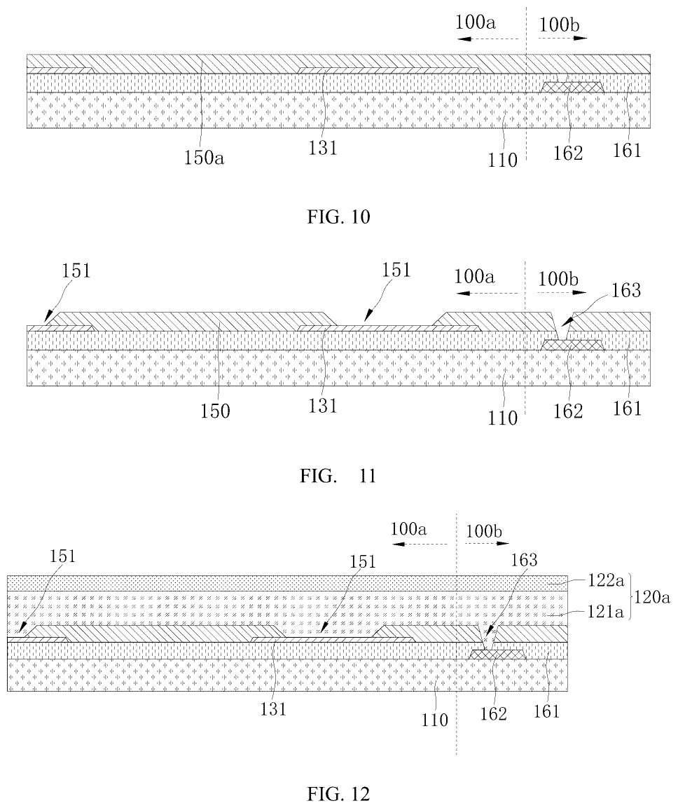

Exemplarily, referring to FIG. 10, after providing the substrate 110, a conductive member 162 may be formed on the substrate 110 of the non-display region 100b. For example, the conductive member 162 may be a second power line. The second power line may be configured to electrically connect to the first partition structure 120 that is subsequently formed in the non-display region 100b.

Exemplarily, referring to FIG. 10, after forming the conductive member 162, an insulating layer 161 may be formed on a side of the conductive member 162 away from the substrate 110. For example, the insulating layer 161 may be a planarization layer. The planarization layer provides good planar support for the light-emitting device 130 that is subsequently formed.

For example, referring to FIG. 10, the method may further include: after forming the insulating layer 161, forming a first electrode 131 on a side of the insulating layer 161 away from the substrate 110.

At S200, a first partition structure and a second partition structure are formed and spaced apart from each other on a side of the substrate. The first partition structure encloses a plurality of opening groups and a second opening. The opening groups and the second openings are spaced apart, each opening group includes a plurality of first openings that are spaced apart. The second partition structure is located in the second opening, and a gap is formed between the second partition structure and the first partition structure.

Referring to FIGS. 14 and 15, the method may further include: after forming the first electrode 131, forming the first partition structure 120 and the second partition structure 140 on the side of the first electrode 131 away from the substrate 110. The first partition structure 120 encloses a plurality of opening groups 123a and a second opening 124. The opening groups 123a and the second openings 124 are spaced apart, each opening group 123a includes a plurality of first openings 123 spaced apart. The second partition structure 140 is located in the second opening 124, and a gap is formed between the second partition structure 140 and the first partition structure 120. In this way, by disposing the second partition structure 140 in the second opening 124 of the first partition structure 120, it is beneficial to reduce the total thickness of the first partition structure 120 and the second partition structure 140 in the display panel 100, which is beneficial to make the display panel 100 thinner and lighter.

Exemplarily, referring to FIG. 10, prior to forming the first partition structure 120 and the second partition structure 140 spaced apart on the side of the substrate 110, the method may further include: forming a pixel definition material layer 150a on a side of the first electrode 131 away from the substrate 110. The pixel definition material layer 150a may be located in the display region 100a and the non-display region 100b. The pixel definition material layer 150a is disposed between the substrate 110 and the first partition structure 120. Referring to FIG. 11, the pixel definition material layer 150a and the insulating layer 161 of the non-display region 100b are patterned to form a via hole 163 in the pixel definition material layer 150a and the insulating layer 161 of the non-display region 100b. The conductive member 162 may be electrically connected to the first partition structure 120 that is formed subsequently, through the via hole 163.

In the related art I, the method may further include: after forming the via hole 163 in the pixel definition material layer 150a of the non-display region 100b, forming a first partition structure 120 and a second partition structure 140 on a side of the pixel definition material layer 150a away from the substrate 110, and then forming a pixel opening 151 on the pixel definition layer 150. The forming the pixel opening 151 on the pixel definition layer 150 may include: forming a photoresist layer on a side of the first partition structure 120 and a side of the second partition structure 140 away from the substrate 110, and the photoresist layer filling the first openings 123 and the gap between the first partition structure 120 and the second partition structure 140, and then patterning the photoresist layer to remove the photoresist layer corresponding to the pixel opening 151 to be formed. The remaining photoresist layer is configured to protect the first partition structure 120 and the second partition structure 140 when etching the pixel definition material layer 150a to form the pixel opening 151. If the gap between the first partition structure 120 and the second partition structure 140 is too narrow, in the process of forming the photoresist layer, when the photoresist layer enters the gap between the first partition structure 120 and the second partition structure 140, it is not easy to discharge the gas in the gap, so that there is more gas in the photoresist layer in the gap and bubbles may be formed. As such, in the subsequent heating process, the volume of the gas in the photoresist layer in the gap increases, causing the photoresist to explode, so that the photoresist layer cannot play a protective role in the subsequent etching process. In addition, after the photoresist explodes, the sputtering will contaminate the display panel 100, thereby affecting the performance of the display panel 100 and even causing the display panel 100 to be scrapped. Therefore, it is necessary to set the distance b1 between the first partition structure 120 and the second partition structure 140 to be large to prevent the above technical problems, which may in turn result in a small aperture ratio of the display panel 100 in the related art.

In order to address the technical problems in the related art I, in one embodiment, in the process of patterning the pixel definition material layer 150a of the non-display region 100b, the method can further include synchronously patterning the pixel definition material layer 150a of the display region 100a to form the pixel openings 151 in the pixel definition material layer 150a of the display region 100a, that is, subjected to the same patterning process to synchronously form the via hole 163 and the pixel opening 151. The remaining pixel definition material layer 150a is formed into the pixel definition layer 150. In this way, since the pixel openings 151 has been formed before the first partition structure 120 and the second partition structure 140 are formed, there is no technical problem in the related art I resulting from that the pixel openings 151 are formed after the first partition structure 120 and the second partition structure 140 are formed. Thus, there is no need to consider the exploding problem in the related art I, so that the distance b1 between the first partition structure 120 and the second partition structure 140 can be set to be small, so as to increase the aperture ratio of the display panel 100. For example, the first distance b1 between the orthographic projection of the first partition structure 120 on the substrate 110 and the orthographic projection of the second partition structure 140 on the substrate 110 can be in a range of 6 μm to 6.5 μm. For example, the distance a between adjacent two pixel opening groups 151a can be in a range of 34 μm to 42.5 μm.

In the related art II, referring to FIGS. 12 and 15, forming the first partition structure 120 and the second partition structure 140 spaced apart on the side of the substrate 110 may include forming an partition material layer 120a on the side of the substrate 110, patterning the partition material layer 120a to simultaneously form the first openings 123 and the gap between the first partition structure 120 and the second partition structure 140 in the partition material layer 120a. The remaining partition material layer 120a is formed into the first partition structure 120 and the second partition structure 140. For example, the partition material layer 120a includes a third partition material layer 121a and a fourth partition material layer 122a. The etching rate of the third partition material layer 121a is greater than the etching rate of the fourth partition material layer 122a, so that after patterning, a concave undercut structure is formed between the sidewall of the third partition portion 121 away from the second partition structure 140 and the fourth partition portion 122. However, when etching the third partition material layer 121a and the fourth partition material layer 122a, in order to ensure the integrity of the undercut structure, the third partition material layer 121a and the fourth partition material layer 122a need to be over-etched many times, and due to the use of the same patterning process, the side of the first partition structure 120 facing the second partition structure 140 and the second partition structure 140 are substantially over-etched, so that after the partition material layer 120a is patterned, the distance b1 between the first partition structure 120 and the second partition structure 140 could be large, which is disadvantageous to increase the aperture ratio of the display panel 100. Referring to FIGS. 4 and 5, a=b11+b12+c1+c2+c3+d1+d2+e1+e2+e3+e4+e5+e6.

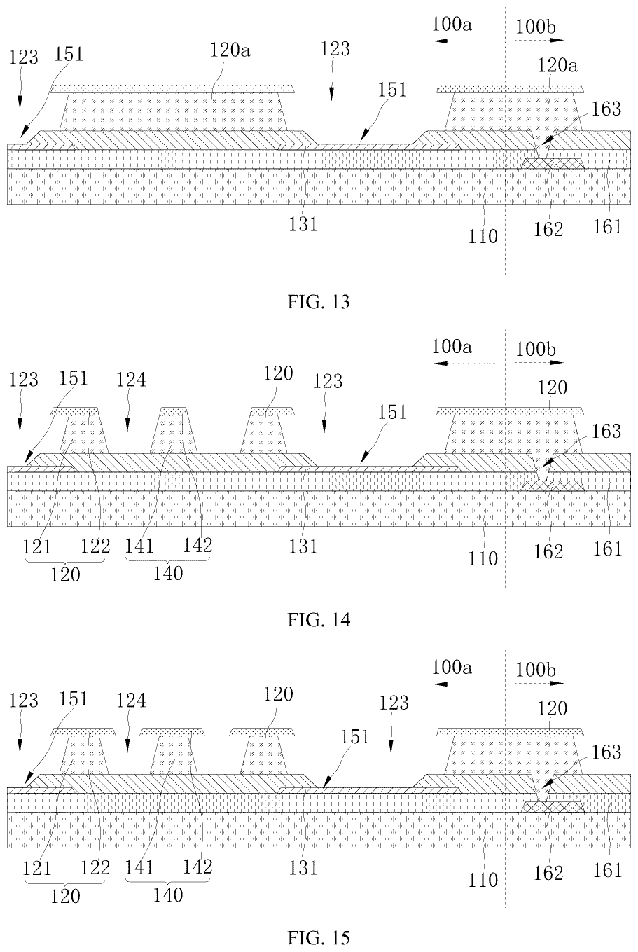

In order to address the technical problems in the related art II, in one embodiment, the forming the first partition structure 120 and the second partition structure 140 spaced apart on the side of the substrate 110 may include forming the third partition material layer 121a on the side of the substrate 110 as shown in FIG. 12, and then, performing a first patterning process on the third partition material layer 121a to form the first openings 123 in the third partition material layer 121a as shown in FIG. 13 so as to form a concave undercut structure between the sidewall of the third partition portion 121 away from the second partition structure 1410 and the fourth partition portion 122. Then, a second patterning process is performed on the third partition material layer 121a (for example, the second patterning process is performed on the third partition material layer 121a located between adjacent two opening groups 123a) to form the gap in the partition material layer 120a. The remaining partition material layer 120a is formed into the first partition structure 120 and the second partition structure 140. Since the second patterning process is configured to form the gap, and the first partition structure 120 and the second partition structure 140 at the gap do not need to have an undercut structure to be formed, there is no need to over-etch the partition material layer 120a at the gap, so that the distance b1 between the first partition structure 120 and the second partition structure 140 can be greatly reduced, thereby improving the aperture ratio of the display panel 100. Referring to FIG. 6, a=b11+b12+c1+c2+c3+d1+d2+e3+e6. For example, the first distance b1 between the orthographic projection of the first partition structure 120 on the substrate 110 and the orthographic projection of the second partition structure 140 on the substrate 110 can be further reduced to be in a range of 3 μm to 3.5 μm. For example, the distance a between adjacent two pixel opening groups 151a can be in a range of 24 μm to 30.5 μm.

It can be understood that the embodiments of the present disclosure can address only the technical problems in related art I, or only the technical problems in related art II, or the technical problems in both the related art I and the related art II.

At S300, a plurality of light-emitting units are formed on a side of the substrate facing the first partition structure. The light-emitting units and the first openings are arranged in correspondence, and at least a portion of the light-emitting unit is located in the corresponding first opening.

Referring to FIG. 1, the method may further include: after forming the first partition structure 120 and the second partition structure 140 spaced apart on the side of the substrate 110, forming the plurality of light-emitting units 133 on the side of the substrate 110 facing the first partition structure 120. The light-emitting units 133 and the first openings 123 are disposed in correspondence. At least a portion of the light-emitting unit 133 is located in the corresponding first opening 123.

Exemplarily, referring to FIG. 1, the method may further include: after forming the plurality of light-emitting units 133 on the side of the substrate 110 facing the first partition structure 120, forming a second electrode 132, an encapsulation layer, etc. on the side of the light-emitting unit 133 away from the substrate 110.

In the case of using “including”, “having”, and “comprising” described herein, another component may be encompassed unless a clear limiting term such as “only”, “consisting of”, etc. is used. Unless mentioned otherwise, a term in the singular form may include a plural form and should not be understood as being one in number.

The technical features of the above embodiments can be combined arbitrarily. In order to make the description concise, not all possible combinations of the technical features are described in the embodiments. However, as long as there is no contradiction in the combination of these technical features, the combinations should be considered as in the scope of the specification.

The above embodiments only illustrate several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be subjected to the appended claims.

What is claimed is:

1. A display panel, comprising:
a substrate;
a first partition structure disposed on a side of the substrate, the first partition structure enclosing a plurality of opening groups comprising at least one first opening, and a second opening located between adjacent two of the opening groups;
a plurality of light-emitting units disposed on the side of the substrate, each light-emitting unit at least partially disposed in a corresponding first opening; and
a second partition structure disposed in the second opening; and
a gap formed between the second partition structure and the first partition structure.

2. The display panel according to claim 1, wherein a distance between an orthographic projection of the first partition structure on the substrate and an orthographic projection of the second partition structure on the substrate is defined as a first distance, and the first distance is in a range of 6 μm to 6.5 μm;
or, the second partition structure has a first orthographic projection on the substrate, the second partition structure comprises a first partition portion and a second partition portion, and the first partition portion is located on a side of the second partition portion facing the substrate; wherein at least one of the first partition portion and the second partition portion is configured as a touch electrode;
or, the opening groups comprises a first opening group and a second opening group adjacent to the first opening group, the second opening is located between the first opening group and the second opening group, an orthographic projection of the first partition portion on the substrate comprises a first edge adjacent to the first opening group and a second edge adjacent to the second opening group, and an orthographic projection of the second partition portion on the substrate comprises a third edge adjacent to the first opening group and a fourth edge adjacent to the second opening group; wherein a distance between the first edge and the second edge is in a range of 4 μm to 4.5 μm;
or, a distance between the adjacent two opening groups is greater than a distance between adjacent two first openings in a same opening group.

3. The display panel according to claim 2, wherein the first partition structure comprises a third partition portion and a fourth partition portion, the fourth partition portion is located on a side of the third partition portion away from the substrate, the first partition structure between the adjacent two opening groups comprises a first partition sub-structure located in the first opening group, and a second partition sub-structure located in the second opening group, and the second partition structure is located between the first partition sub-structure and the second partition sub-structure;
wherein in the first partition sub-structure, an orthographic projection of the third partition portion on the substrate comprises a fifth edge adjacent to the second partition structure and a sixth edge adjacent to the first opening group, and an orthographic projection of the fourth partition portion on the substrate comprises a seventh edge adjacent to the second partition structure and an eighth edge adjacent to the first opening group;
in the second partition sub-structure, an orthographic projection of the third partition portion on the substrate comprises a ninth edge adjacent to the second partition structure and a tenth edge adjacent to the second opening group, and an orthographic projection of the fourth partition portion on the substrate comprises an eleventh edge adjacent to the second partition structure and a twelfth edge adjacent to the second opening group; wherein at least one of a distance between the fifth edge and the sixth edge and a distance between the ninth edge and the tenth edge is in a range of 4 μm to 4.5 μm; or, at least two of the distance between the fifth edge and the sixth edge, the distance between the ninth edge and the tenth edge, and the distance between the first edge and the second edge are the same
wherein a distance between an orthographic projection of the first partition sub-structure on the substrate and an orthographic projection of the second partition structure on the substrate is equal to a distance between an orthographic projection of the second partition sub-structure on the substrate and the orthographic projection of the second partition structure on the substrate;
wherein at least one of the fourth partition portion and the third partition portion comprises a conductive material; or, the third partition part and the first partition part are disposed on a same layer; or, the fourth partition portion and the second partition portion are disposed on a same layer.

4. The display panel according to claim 3, wherein the first edge and the second edge are located between the third edge and the fourth edge; and the seventh edge and the eleventh edge are located between the fifth edge and the ninth edge;
the distance between the orthographic projection of the first partition sub-structure on the substrate and the orthographic projection of the second partition structure on the substrate is equal to a distance between the third edge and the seventh edge, and the distance between the orthographic projection of the second partition sub-structure on the substrate and the orthographic projection of the second partition structure on the substrate is equal to a distance between the fourth edge and the eleventh edge;
wherein at least one of a distance between the first edge and the third edge, a distance between the second edge and the fourth edge, a distance between the fifth edge and the seventh edge, and a distance between the ninth edge and the eleventh edge is in a range of 1 μm to 1.5 μm;
or, at least two of the distance between the first edge and the third edge, the distance between the second edge and the fourth edge, the distance between the fifth edge and the seventh edge, and the distance between the ninth edge and the eleventh edge are the same.

5. The display panel according to claim 3, wherein the third edge and the fourth edge are located between the first edge and the second edge, and the fifth edge and the ninth edge are located between the seventh edge and the eleventh edge;
or, in the first partition sub-structure, the seventh edge is located within an orthographic projection of a surface of the third partition portion away from the substrate on the substrate;
or, in the second partition sub-structure, the eleventh edge is located within an orthographic projection of the surface of the third partition portion away from the substrate on the substrate;
or, at least one of the third edge and the fourth edge is located within an orthographic projection of a surface of the first partition portion away from the substrate on the substrate;
or, a distance between the first partition structure and the second partition structure gradually increases in a direction from the substrate to the first partition structure;
or, the distance between the orthographic projection of the first partition sub-structure on the substrate and the orthographic projection of the second partition structure on the substrate is equal to a distance between the first edge and the fifth edge, and the distance between the orthographic projection of the second partition sub-structure and the orthographic projection of the second partition structure on the substrate is equal to a distance between the second edge and the ninth edge;
or, the first distance is in a range of 3 μm to 3.5 μm.

6. The display panel according to claim 3, wherein the sixth edge and the tenth edge are located between the eighth edge and the twelfth edge;
or, at least one of a distance between the sixth edge and the eighth edge and a distance between the tenth edge and the twelfth edge is in a range of 1 μm to 1.5 μm.

7. The display panel according to claim 6, further comprising a pixel definition layer disposed between the substrate and the first partition structure,
wherein the pixel definition layer encloses a plurality of pixel opening groups corresponding to the plurality of opening groups, each of the pixel opening groups comprises a plurality of pixel openings, each first opening is in communication with a pixel opening, and an orthographic projection of the pixel opening on the substrate is located within an orthographic projection of the first opening on the substrate;
adjacent two pixel opening groups comprise a first pixel opening group and a second pixel opening group, the first pixel opening group and the first opening group are disposed in correspondence, and the second pixel opening group and the second opening group are disposed in correspondence;
an orthographic projection of a portion of the pixel definition layer located between the adjacent two pixel opening groups on the substrate comprises a thirteenth edge adjacent to the first pixel opening group and a fourteenth edge adjacent to the second pixel opening group;
wherein a distance between the adjacent two pixel opening groups is greater than a distance between adjacent two pixel openings in a same pixel opening group;
or, at least one of a distance between the eighth edge and the thirteenth edge and a distance between the twelfth edge and the fourteenth edge is in a range of 2 μm to 3.5 μm;
or, the distance between the eighth edge and the thirteenth edge is equal to the distance between the twelfth edge and the fourteenth edge;
or, the display panel comprises a display region and a non-display region that are adjacent to each other, the pixel opening is located in the display region, and in the non-display region, the pixel definition layer encloses a via hole.

8. The display panel according to claim 7, wherein in the same pixel opening group, the distance between adjacent two pixel openings is in a range of 12 μm to 14 μm;
or, the distance between adjacent two pixel opening groups is in a range of 34 μm to 42.5 μm;
or, the distance between adjacent two pixel opening groups is in a range of 24 μm to 30.5 μm.

9. The display panel according to claim 3, wherein a width of the third partition portion in a direction from the first opening group to the second opening group is defined as a first width, and the first width gradually decreases in a direction from the substrate to the first partition structure;
or, the third partition portion comprises a first partition sub-portion and a second partition sub-portion, the second partition sub-portion is located on a side of the first partition sub-portion away from the fourth partition portion, and an orthographic projection of the first partition sub-portion on the substrate is located within an orthographic projection of the second partition sub-portion on the substrate.

10. The display panel according to claim 3, wherein a width of the first partition portion in a direction from the first opening group to the second opening group is defined as a second width, and the second width gradually decreases in a direction from the substrate to the first partition structure;
or, the first partition portion comprises a third partition sub-portion and a fourth partition sub-portion, the fourth partition sub-portion is located on a side of the third partition sub-portion away from the second partition portion, and an orthographic projection of the third partition sub-portion on the substrate is located within an orthographic projection of the fourth partition sub-portion on the substrate.

11. A method for manufacturing a display panel, comprising:
providing a substrate;
forming a first partition structure and a second partition structure that are spaced apart on a side of the substrate; the first partition structure enclosing a plurality of opening groups comprising a plurality of first openings, and a second opening, the second opening being located between adjacent two opening groups, and the second partition structure being located in the second opening; and
forming a plurality of light-emitting units on a side of the substrate facing the first partition structure, and each light-emitting unit being at least partially disposed in a corresponding first opening.

12. The method according to claim 11, wherein a distance between an orthographic projection of the first partition structure on the substrate and an orthographic projection of the second partition structure on the substrate is a first distance, and the first distance is in a range of 6 μm to 6.5 μm;
or, the display panel comprises a display region and a non-display region that are adjacent to each other; prior to forming the first partition structure and the second partition structure that are spaced apart on the side of the substrate, the method further comprises:
forming a pixel definition material layer on the side of the substrate, the pixel definition material layer being located in the display region and the non-display region, and the pixel definition material layer being disposed between the substrate and the first partition structure; and
patterning the pixel definition material layer in the non-display region to form a via hole in the pixel definition material layer in the non-display region.

13. The method according to claim 12, wherein during patterning the pixel definition material layer in the non-display region, the method further comprises:
patterning the pixel definition material layer in the display region simultaneously to form a plurality of pixel openings in the pixel definition material layer of the display region; and
forming a remaining pixel definition material layer into a pixel definition layer;
wherein each first opening is in communication with a pixel opening, and an orthographic projection of the pixel opening on the substrate is located within an orthographic projection of the first opening on the substrate.

14. The method according to claim 11, wherein forming the first partition structure and the second partition structure that are spaced apart on the side of the substrate comprises:
forming an partition material layer on the side of the substrate;
performing a first patterning process on the partition material layer to form the plurality of first openings in the partition material layer;
performing a second patterning process on the partition material layer to form a gap in the partition material layer; and
forming a remaining partition material layer into the first partition structure and the second partition structure.

15. The method according to claim 12, wherein the first distance is in a range of 3 μm to 3.5 μm.

16. A display panel, comprising:
a substrate;
a first partition structure disposed on a side of the substrate, the first partition structure enclosing a plurality of opening groups comprising at least one first opening, and a second opening located between adjacent two of the opening groups;
a plurality of light-emitting units disposed on the side of the substrate, each light-emitting unit being at least partially disposed in a corresponding first opening; and
a plurality of second partition structure disposed in the second opening at intervals, and a gap being formed between the second partition structure and the first partition structure.
